(19) United States
(12) Patent Application Publication
(10) Pub. No.: US 2024/0260180 A1
(43) Pub. Date: Aug. 1, 2024

(54) WIRING BOARD AND ELECTRONIC DEVICE

(71) Applicant: Kioxia Corporation, Tokyo (JP)

(72) Inventor: Shuichi TAKADA, Yokohama Kanagawa (JP)

(21) Appl. No.: 18/540,044

(22) Filed: Dec. 14, 2023

(30) Foreign Application Priority Data
Jan. 26, 2023 (JP) 2023-010504

(51) Int. Cl. H05K 1/02

(52) U.S. Cl. CPC H05K 1/0298; H05K 1/0245; H05K 2201/10015; H05K 2201/10174

(57) ABSTRACT

A wiring board includes: a substrate having a first surface; a terminal disposed to the first surface of the substrate; a wiring pattern connected to the terminal on the first surface and configured to transmit a signal; and a reference voltage layer to which a reference voltage is configured to be applied, the reference voltage layer being disposed inside the substrate or to a second surface, which is opposite to the first surface, a line width of the wiring pattern in a wiring region including a portion connecting to a capacitive component being narrower than a line width of the wiring pattern at a portion other than the wiring region, the reference voltage layer being partially removed at a portion overlapping the wiring region when the substrate is viewed from above.

### CROSS REFERENCE TO RELATED APPLICATIONS

This application is based upon and claims the benefit of priority from the prior Japanese Patent Application No. 2023-010504, filed on Jan. 26, 2023, the entire contents of which are incorporated herein by reference.

### FIELD

Embodiments of the present invention relate to a wiring board and an electronic device.

### BACKGROUND

An example of an electronic device in which a terminal for external connection is exposed includes a Solid State Drive (SSD). In such an electronic device, a surge voltage caused by an electrostatic discharge (ESD) may be applied to the exposed terminal. In order to avoid electrostatic breakdown caused in electronic components of the electronic device, a protection circuit to the electrostatic may be provided to a wiring pattern connected to the terminal.

The protection circuit includes a capacitive component. If the parasitic capacitance of the wiring pattern increases, impedance mismatch occurs. It may be possible that the insertion loss increases and the return loss decreases in signal transmission through the wiring pattern with the protection circuit.

### BRIEF DESCRIPTION OF THE DRAWINGS

FIG. 1 is a block diagram illustrating a schematic configuration of a memory system according to an embodiment.

FIG. 2 is an external view of an SSD.

FIG. 3 is a plan view schematically showing terminals on a wiring board of the SSD, and wiring patterns connecting to the terminals.

FIG. 4 is a plan view obtained by partially enlarging FIG. 3.

FIG. 5 is an equivalent circuit diagram around a connecting portion between a wiring pattern and a TVS diode.

FIG. 6 is a cross-sectional view taken along line A-A in FIG. 4.

FIG. 7 is a cross-sectional view taken along line B-B in FIG. 4.

FIG. 8 is a cross-sectional view taken along line C-C in FIG. 4.

FIG. 9 is a diagram schematically showing changes in impedance of a wiring pattern having a constant line width.

FIG. 10 is a diagram schematically showing changes in impedance of the wiring pattern in the embodiment.

### DETAILED DESCRIPTION

According to one embodiment, a wiring board includes:
a substrate having a first surface;
a terminal disposed to the first surface of the substrate;
a wiring pattern connected to the terminal on the first surface and configured to transmit a signal; and
a reference voltage layer to which a reference voltage is configured to be applied, the reference voltage layer being disposed inside the substrate or to a second surface, which is opposite to the first surface, wherein
a line width of the wiring pattern in a wiring region including a portion connecting to a capacitive component is narrower than a line width of the wiring pattern at a portion other than the wiring region, and
the reference voltage layer is partially removed at a portion overlapping the wiring region when the substrate is viewed from above.

A wiring board and an electronic device according to embodiments will be described below with reference to the accompanying drawings. In the following descriptions, major components of the wiring board and the electronic device will be mainly explained. However, the wiring board and the electronic device may have a component or a function that is not described herein or illustrated in the drawings. The following descriptions do not exclude such a component or function.

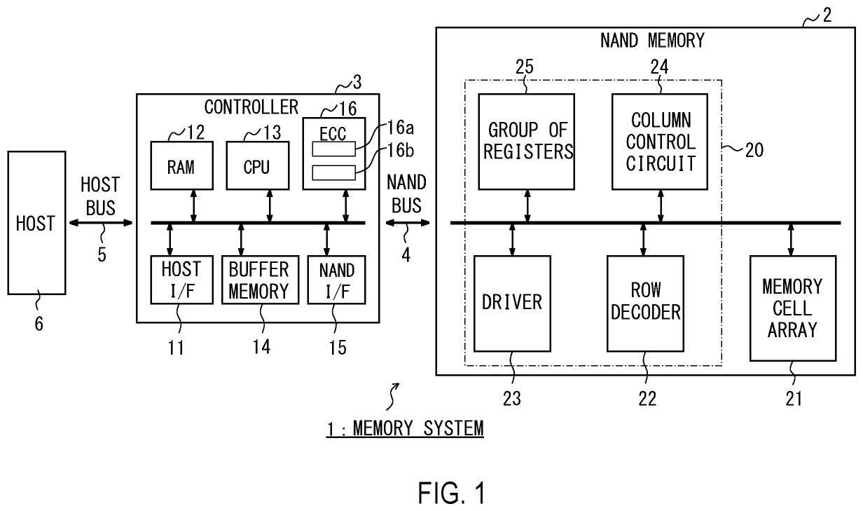

FIG. 1 is a block diagram illustrating a schematic configuration of a memory system 1 according to an embodiment. The memory system 1 may be housed in various types of electronic devices. The memory system 1 shown in FIG. 1 has a configuration of an SSD including a NAND flash memory (hereinafter simply referred to as “NAND memory”) 2. The memory system 1 shown in FIG. 1 may be applied to various systems other than SSDs, such as a Universal Flash Storage (UFS) device, a Multi Media Card (MMC), an SD card, or a Universal Serial Bus (USB) memory. Furthermore, the memory system 1 shown in FIG. 1 may include a nonvolatile memory other than the NAND memory (such as a Magnetoresistive Random Access Memory (MRAM), a Resistive Random Access Memory (ReRAM), or a Phase-change Random Access Memory (PRAM)), or a volatile memory (such as a Dynamic Random Access Memory (DRAM) or a Static Random Access Memory (SRAM)).

The memory system 1 shown in FIG. 1 includes the NAND memory 2 and a controller 3. The specific configuration of the NAND memory 2 will be described later.

The controller 3 is connected to the NAND memory 2 via a NAND bus 4 to control the NAND memory 2. The controller 3 may be connected to a host device (hereinafter simply referred to as “host”) 6 via a host bus 5. In response to an instruction received from the host 6 via the host bus 5, the controller 3 accesses the NAND memory 2 via the NAND bus 4. The host 6 is an electronic device such as a personal computer or a server. The host bus 5 complies with an interface standard such as the PCIe™, the UFS, or the Ethernet™. The NAND bus 4 complies with an interface standard such as the Toggle IF. The controller 3 transmits a signal to and receives a signal from the host 6 and the NAND memory 2 in accordance with a predefined interface standard.

The controller 3 includes a host interface circuit (host I/F) 11, a built-in memory (RAM) 12, a processor (CPU) 13, a buffer memory 14, a NAND interface circuit (NAND I/F) 15, and an Error Checking and Correcting (ECC) circuit 16. The components of the controller 3 are not limited to those shown in FIG. 1, but may include others. The controller 3 may be formed as a circuitry such as a System-on-a-Chip (SoC) including the components sealed in a package.

The host interface circuit 11 is connected to the host 6 via the host bus 5 and transmits instructions and data received from the host 6 to the CPU 13 and the buffer memory 14. Furthermore, the host interface circuit 11 causes the buffer memory 14 to transmit stored data to the host 6 in response to an instruction from the CPU 13.

The CPU 13 controls the operations of the controller 3. For example, when a write instruction is received from the host 6, the CPU 13 sends the write instruction to the NAND interface circuit 15. Furthermore, when a read instruction or erase instruction is received, the CPU 13 sends such an instruction to the NAND interface circuit 15. The CPU 13 also performs various processing operations for managing the NAND memory 2, including garbage collection, refresh, and wear leveling. The operations of the controller 3 described below may be realized by firmware executed by the CPU 13 or by hardware.

The NAND interface circuit 15 is connected to the NAND memory 2 via the NAND bus 4, and communicates with the NAND memory 2. The NAND interface circuit 15 sends data to be written and a control signal to the NAND memory 2 based on a write instruction received from the CPU 13. Furthermore, the NAND interface circuit 15 sends a read request to the NAND memory 2 based on a read instruction received from the CPU 13 in order to receive data to be read and a control signal from the NAND memory 2. The buffer memory 14 temporarily stores the data to be written and the data to be read.

The RAM 12 is a semiconductor memory such as a DRAM or an SRAM, and used for a working space of the CPU 13. The RAM 12 stores firmware executed by the CPU 13, and various types of management information for managing the NAND memory 2. The RAM 12 may be disposed outside the controller 3.

The ECC circuit 16 performs an operation relating to error detection and error correction with respect to the data to be stored in the NAND memory 2. The ECC circuit 16 includes an encoder 16a and a decoder 16b. As data is written, the encoder 16a generates an error correction code, and adds the error correction data to the written data. The decoder 16b detects an error included in data read from the NAND memory 2, and corrects the detected error using the error correction code.

The NAND memory 2 includes a peripheral circuit 20 and a memory cell array 21. The peripheral circuit 20 includes a row decoder 22, a driver 23, a column control circuit 24, and a group of registers 25. The peripheral circuit 20 is connected to the controller 3 via the NAND bus 4.

The memory cell array 21 includes a plurality of blocks including a plurality of nonvolatile memory cells associated with rows and columns. The reading of data from and the writing of data to the memory cell array 21 are controlled by the peripheral circuit 20.

The memory system 1 is constituted by mounting the respective components shown in FIG. 1 and terminals (called pads or pins) for connecting external elements on a wiring board. At least some of the components shown in FIG. 1 may be mounted on the wiring board in the form of one or more integrated circuit (IG) chips, or as discrete components.

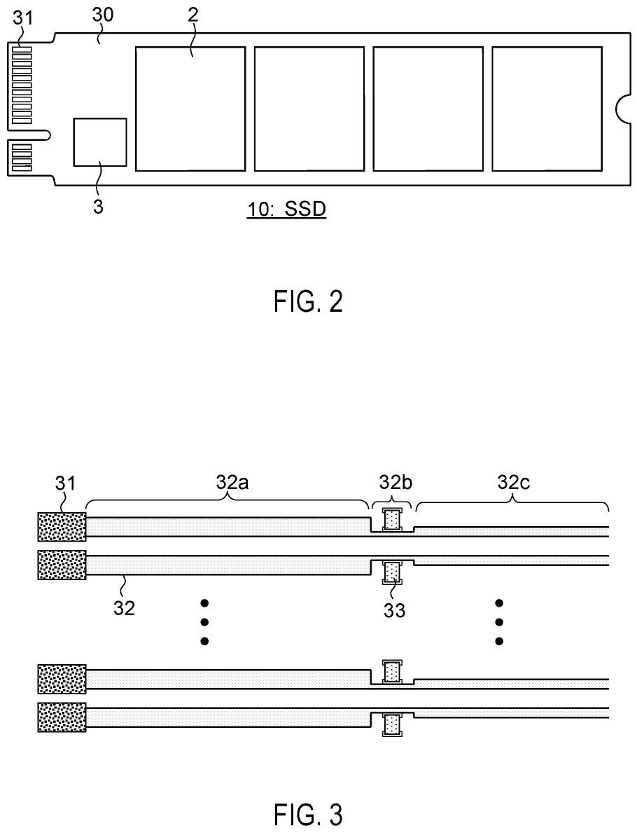

FIG. 2 is an external view of an SSD 10, which is an example of the memory system 1. As shown in FIG. 2, the SSD 10 has a wiring board 30 having rectangular shape and a plurality of terminals 31 arranged along one side of the wiring board 30. FIG. 2 shows an example in which the wiring board 30 and the terminals 31 are both exposed, but the SSD 10 may include a housing to cover the wiring board 30, so that only the terminals 31 are exposed. The terminals 31 are disposed along one side of a first surface and a second surface that is opposite to the first surface of the wiring board 30 of the SSD 10. Each terminal 31 is connected to a wiring pattern that is not shown in FIG. 2. Each wiring pattern is connected to a corresponding terminal 31 on the first surface or the second surface.

A plurality of components including a plurality of NAND memories 2 and a controller 3 are mounted on the wiring board 30. For the simplicity, FIG. 2 only shows the NAND memories 2 and the controller 3, and other components are omitted.

There are a plurality of standards that may be applied to the SSD 10. The number and the shape of the terminals 31 vary depending on which standard is selected. The terminals 31 of the SSD 10 are so-called male terminals, and exposed. The exposed terminals 31 are detachably connected to sockets of a main circuit board included in the host device 6.

FIG. 3 is a plan view schematically showing the terminals 31 on the wiring board 30 of the SSD 10 and the wiring patterns 32 connecting to the terminals 31. In the example shown in FIG. 3, the wiring patterns 32 connecting to the terminals 31 are disposed to have constant intervals, and to be substantially parallel to each other. The locations and the line widths of the wiring patterns 32 are not limited to those shown in FIG. 3.

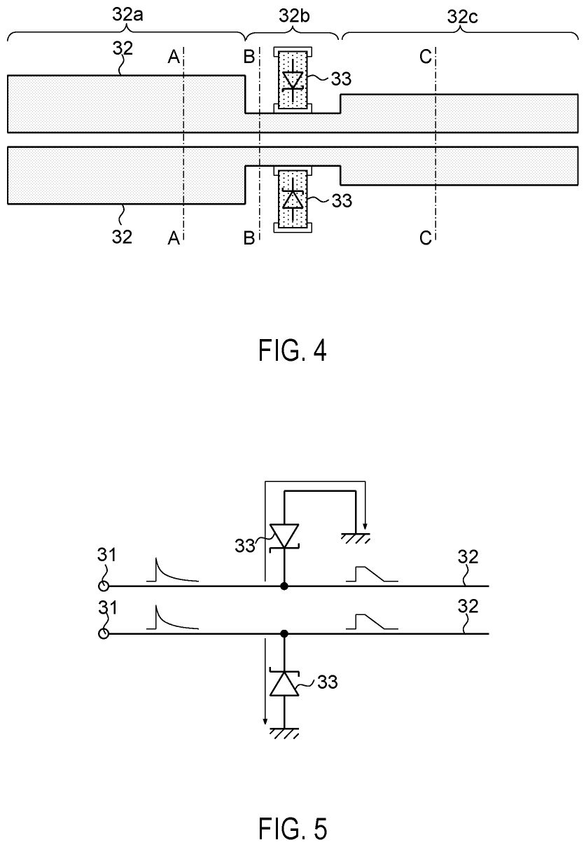

FIG. 4 is a plan view obtained by partially enlarging FIG. 3. In order to improve the noise resistance, the SSD 10 performs signal transmission with differential signals with respect to at least a part of the signals. FIG. 4 shows two wiring patterns 32 connected to a pair of terminals 31 used for a pair of differential signals. Since a group of terminals 31 is exposed in the SSD 10 as described above, a surge voltage caused by an electrostatic discharge may be applied to the group of terminals. In order to avoid this, a transient voltage suppressor (TVS) diode or a Zener diode 33 may be connected to a wiring pattern 32 connecting to a corresponding terminal 31. An example in which a TVS diode 33 is connected to the wiring pattern 32 connecting to the terminal 31 on the wiring board 30 will be described herein.

FIG. 5 is an equivalent circuit diagram around a connecting portion between the wiring pattern 32 and the TVS diode 33. As shown in FIG. 5, the cathode of each TVS diode 33 is connected to a corresponding wiring pattern 32, and the anode is connected to a ground node. A reference voltage for operating the controller 3 of the SSD 10 is applied to the ground node. As the surge voltage caused by the electrostatic discharge is applied to the wiring pattern 32, the surge voltage is clamped by the TVS diode 33. As a result, the voltage of the wiring pattern 32 connecting to the cathode of the TVS diode 33 does not become greater than the clamp voltage of the TVS diode 33. Thus, the surge voltage is curbed.

The terminals 31 of the SSD 10 are disposed on the left side of the wiring patterns 32 shown in FIG. 4, and an IC chip such as the controller 3 of the SSD 10 is electrically connected on the right side. As shown in FIG. 4, the line width of the wiring pattern 32 on the wiring board 30 in this embodiment is not constant on the wiring board 30, but varies depending on the location. For example, a specific wiring region of the wiring pattern 32 including the connecting portion where the TVS diode 33 is connected to the wiring pattern 32 is narrower than other regions of the wiring pattern 32.

A reference voltage layer is disposed to a wiring layer inside the wiring board 30. For example, the reference voltage layer is connected to the ground node, and also called “ground layer.” In the wiring board 30 according to this embodiment, the reference voltage layer is partially removed at a portion that overlaps the specific wiring region in the plan view (when viewed from above).

As described above, in the wiring board 30 according to this embodiment, the line width of the wiring pattern 32 around the portion connecting to the TVS diode 33 is adjusted, and the reference voltage layer is partially removed to control the impedance of the wiring pattern 32, thereby curbing the impedance mismatch in the wiring pattern 32.

A plurality of reference voltage layers may be stacked in the wiring board 30. For example, a first reference voltage layer (for example, a first ground layer) and a second reference voltage layer (for example, a second ground layer) are stacked in the wiring board 30. The second reference voltage layer is disposed with a first insulating layer disposed between the first reference voltage layer and the second reference voltage layer, and is located to be more distant from the wiring pattern 32 than the first reference voltage layer. In this case, the first reference voltage layer is partially removed at a portion that overlaps the specific wiring region in the plan view.

Alternatively, first to third reference voltage layers may be disposed within the wiring board 30. The third reference voltage layer (for example, a third ground layer) is disposed with a second insulating layer being disposed between the second reference voltage layer and the third reference voltage layer, and located more distant from the wiring pattern 32 than the first reference voltage layer and the second reference voltage layer. In this case, the first reference voltage layer and the second reference voltage layer are partially removed at a portion that overlaps the specific wiring region in the plan view.

As shown in FIG. 4, the wiring pattern 32 on the wiring board 30 of the SSD 10 has a first wiring region 32a, a second wiring region 32b, and a third wiring region 32c. The range of the first wiring region 32a is from the terminal 31 to the specific wiring region. The range of the second wiring region 32b includes the specific wiring region. The third wiring region 32c is disposed opposite to the first wiring region 32a relative to the specific wiring region.

In the wiring board 30 according to this embodiment, the line width in the first wiring region 32a (first line width) is wider than the line width of the second wiring region 32b (second line width) or the line width of the third wiring region 32c (third line width). The line width of the third wiring region 32c is wider than the line width of the second wiring region 32b.

In the wiring board 30 according to this embodiment, the impedance at both sides of the portion connecting to the TVS diode 33 of the second wiring region 32b, i.e., the impedance of portions other than the connecting portion, is higher than the impedance of the connecting portion. This is because the impedance at the portion connecting to the TVS diode 33 decreases due to the capacitance of the footprint needed for the connection and the capacitance of the TVS diode itself. The impedance at both sides of the portion connecting to the TVS diode 33 in the second wiring region 32b is set to be higher than the impedance of the first wiring region 32a and the third wiring region 32c. For the reason described above, the impedance of the portion connecting to the TVS diode 33 in the second wiring region 32b is lower than the impedance of the first wiring region 32a and the third wiring region 32c.

An element, such as a coil or an inductor, may be connected to the third wiring region 32c for impedance matching.

In a case where an element for impedance matching is connected to the third wiring region 32c in the wiring board 30, if the TVS diode 33 is connected to the wiring pattern 32 to deal with the electrostatic discharge, the impedance may be changed. This may cause impedance mismatch.

Specifically, if the TVS diode 33 is connected, the parasitic capacitance of the wiring pattern 32 increases due to the parasitic capacitance depending on the terminal shape of the TVS diode 33 and the parasitic capacitance of the TVS diode 33 itself. This decreases the impedance of the wiring pattern 32 and causes the impedance mismatch.

The wiring board 30 according to this embodiment is intended not to cause the impedance mismatch when the TVS diode 33 is connected to the wiring pattern 32.

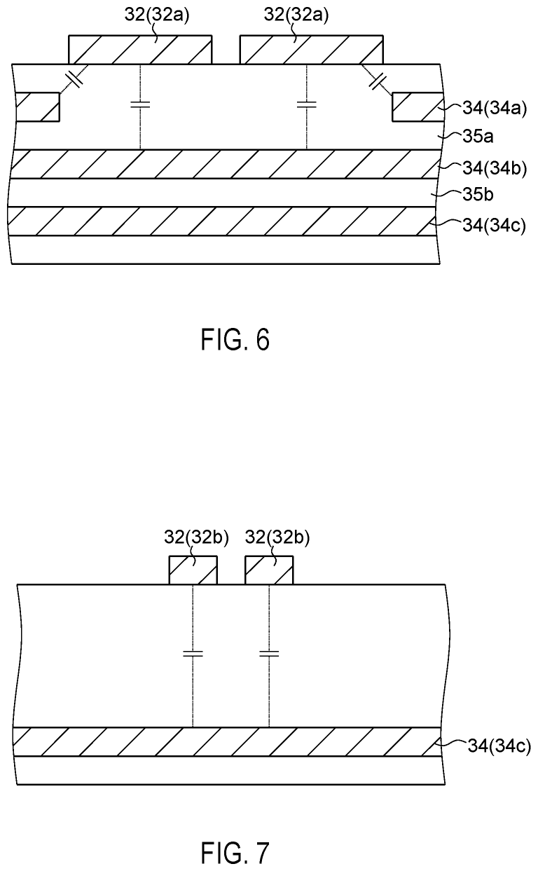

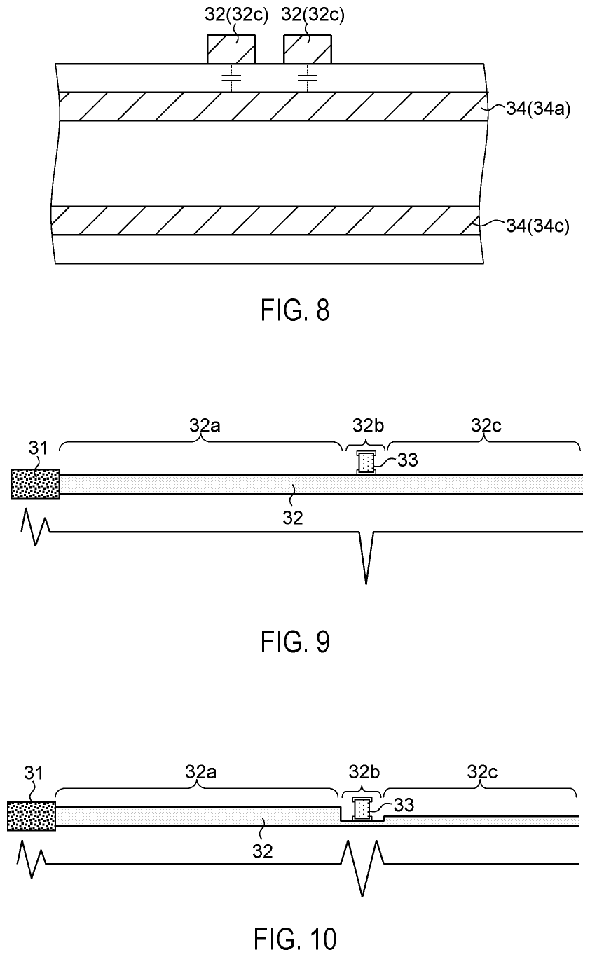

FIG. 6 is a cross-sectional view taken along line A-A in FIG. 4, FIG. 7 is a cross-sectional view taken along line B-B in FIG. 4, and FIG. 8 is a cross-sectional view taken along line C-C in FIG. 4.

The wiring board 30 includes a plurality of reference voltage layers 34. An example in which the reference voltage layers 34 are ground layers will be described below. As shown in FIGS. 6 to 8, under the first surface of the wiring board 30 on which the wiring patterns 32 are disposed, a first ground layer 34a, a second ground layer 34b, and a third ground layer 34c are disposed in this order. An insulating layer 35a is disposed between the first ground layer 34a and the second ground layer 34b, and an insulating layer 35b is disposed between the second ground layer 34b and the third ground layer 34c. Although the second surface, which is opposite to the first surface where the wiring patterns 32 are disposed, does not have any wiring pattern 32 or ground layer in FIGS. 6 to 8, a wiring pattern 32 or a ground layer may be disposed on the second surface. The change in impedance in the configurations shown in FIGS. 6 to 8 will be described later.

FIG. 9 schematically shows changes in impedance of the wiring pattern 32 having a constant line width. FIG. 9 is a diagram for the case where the wiring pattern 32 connecting to the terminal 31 has a constant line width, and each of the first to third ground layers 34a, 34b, and 34c disposed below the wiring pattern 32 is not partially removed but formed as a solid pattern. The underneath of the wiring pattern 32 corresponds to a portion that is below the first surface on which the wiring pattern 32 is disposed. The horizontal axis of the lower part in FIG. 9 represents the distance along the wiring pattern 32 from the terminal 31, and the vertical axis represents the impedance value of the wiring pattern 32.

As shown in FIG. 9, the width of the terminal 31 is different from the width of the wiring pattern 32. This may cause changes in impedance around the terminal 31. Furthermore, the impedance in the second wiring region 32b around the portion connecting to the TVS diode 33 is likely to decrease due to the parasitic capacitance that depends on the shape and the size of the cathode of the TVS diode 33 and the parasitic capacitance of the TVS diode 33 itself. In the third wiring region 32c that is more distant from the terminal 31 than the portion connecting to the TVS diode 33, the line width and the distance to the reference voltage layer are kept constant to maintain the impedance at a certain level.

As shown in FIG. 9, a footprint needed for connecting the TVS diode 33 to the wiring pattern 32 having a constant line width is likely to cause an impedance mismatch. The wiring board 30 according to the embodiment has a configuration with which it is possible to prevent the discontinuity in impedance even if the TVS diode 33 is connected.

FIG. 10 schematically shows changes in impedance of the wiring pattern 32 according to the embodiment. The horizontal axis in the lower portion of FIG. 10 represents the distance from the terminal 31, and the vertical axis represents the impedance value of the wiring pattern 32.

The technical features of the wiring board 30 according to this embodiment will be described below with reference to FIGS. 6 to 8 and 10. The first wiring region 32a from the terminal 31 on the wiring board 30 to the portion connecting to the TVS diode 33 is formed by thickening a portion of the wiring pattern 32 to have a first line width, as shown in FIG. 6. The first ground layer 34a underneath the first wiring region 32a is partially removed at a portion that overlaps the first wiring region 32a when viewed from above. As described above, the impedance is likely to fluctuate in a portion around the terminal 31. Therefore, the line width in the first wiring region 32a of the wiring pattern 32 is increased. Since the first ground layer 34a is partially removed around the terminal 31, the impedance in the first wiring region 32a of the wiring pattern 32 is increased.

The line width of the wiring pattern 32 is decreased to the second line width in the second wiring region 32b around a portion connecting to the TVS diode 33 (the specific wiring region), as shown in FIG. 7. The first ground layer 34a and the second ground layer 34b are partially removed at portions that overlap the second wiring region 32b when viewed from above. The distance between the wiring pattern 32 and the ground layer disposed below (in this case, the third ground layer 34c) may be increased by removing the first ground layer 34a and the second ground layer 34b below the second wiring region 32b, thereby increasing the impedance of the second wiring region 32b as compared to that of the first wiring region 32a. As shown in FIG. 10, the impedance temporality decreases at the portion connecting to the TVS diode 33. However, the impedance at both sides thereof may be increased by narrowing the line width in the second wiring region 32b of the wiring pattern 32, and by partially removing the first ground layer 34a and the second ground layer 34b. As a result, the insertion loss and the return loss of the wiring pattern 32 may be curbed, thereby restricting decrease in average impedance in the second wiring region 32b.

As shown in FIG. 8, the line width of the wiring pattern 32 in the third wiring region 32c, which is located after the portion connecting to the TVS diode 33, is increased to the third line width. Furthermore, in the third wiring region 32c, the second ground layer 34b is partially removed in a region that overlaps the wiring pattern 32 when viewed from above. As a result, the impedance in the third wiring region 32c is lower than that in the second wiring region 32b. As shown in FIG. 10, no impedance fluctuation occurs in the third wiring region 32c, like that in FIG. 9.

In the embodiment described above, the TVS diode 33 or a Zener diode is connected to the wiring pattern 32. However, the circuit board according to the embodiment may apply to a case where a capacitive component other than the TVS diode 33 or the Zener diode is connected to the wiring pattern 32. An example of the capacitive component is a capacitor. A capacitive component decreases the impedance of a circuit pattern when connected to the circuit pattern due to the parasitic capacitance of the component itself and the parasitic capacitance of the terminal of the component.

Thus, in the embodiment, when the TVS diode 33 is connected to the wiring pattern 32 connecting to the terminal 31 of the wiring board 30, the line width of the wiring pattern 32 is adjusted depending on the location of the portion to be adjusted, and the ground layers disposed below the wiring pattern 32 of the wiring board 30 are partially removed. As a result, the insertion loss and the return loss of the wiring pattern 32 may be curbed, and the impedance mismatch of the wiring pattern 32 may be prevented. In more detail, since the impedance decreases at the portion connecting to the TVS diode 33, the line width of the wiring pattern 32 is decreased at both sides of the portion connecting to the TVS diode 33, and the first and second ground layers 34a and 34b are partially removed at a portion below the portion connecting to the TVS diode 33. This curbs fluctuations in average impedance of the portion connecting to the TVS diode 33.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A wiring board comprising:
a substrate having a first surface;
a terminal disposed to the first surface of the substrate;
a wiring pattern connected to the terminal on the first surface and configured to transmit a signal; and
a reference voltage layer to which a reference voltage is configured to be applied, the reference voltage layer being disposed inside the substrate or to a second surface, which is opposite to the first surface, wherein
a line width of the wiring pattern in a wiring region including a portion connecting to a capacitive component is narrower than a line width of the wiring pattern at a portion other than the wiring region, and
the reference voltage layer is partially removed at a portion overlapping the wiring region when the substrate is viewed from above.

2. The wiring board according to claim 1, wherein the wiring pattern includes:
a first wiring region from the terminal to the wiring region;
a second wiring region including the wiring region; and
a third wiring region on an opposite side of the first wiring region relative to the wiring region, wherein
a line width of the first wiring region is wider than a line width of the second wiring region and a line width of the third wiring region, and
the line width of the third wiring region is wider than the line width of the second wiring region.

3. The wiring board according to claim 2, wherein an impedance at both sides of the portion connecting to the capacitive component in the second wiring region is higher than an impedance in the first wiring region and an impedance in the third wiring region.

4. The wiring board according to claim 3, wherein the impedance at both the sides of the portion connecting to the capacitive component in the second wiring region is higher than an impedance at the portion connecting to the capacitive component in the second wiring region.

5. The wiring board according to claim 3, wherein
the first wiring region, the second wiring region, and the third wiring region are disposed in this order from the terminal,
an impedance from a first end of the second wiring region, which is close to the first wiring region, to the portion connecting to the capacitive component is higher than an impedance at the portion connecting to the capacitive component in the second wiring region, and
an impedance from a second end of the second wiring region, which is close to the third wiring region, to the portion connecting to the capacitive component is higher than the impedance at the portion connecting to the capacitive component in the second wiring region.

6. The wiring board according to claim 3, wherein the impedance at the portion connecting to the capacitive component in the second wiring region is lower than the impedance in the first wiring region and the third wiring region.

7. The wiring board according to claim 2, wherein
the first wiring region, the second wiring region, and the third wiring region are disposed in this order from the terminal,
an impedance from a first end of the second wiring region, which is close to the first wiring region, to the portion connecting to the capacitive component is higher than an impedance in the first wiring region and an impedance in the third wiring region,
an impedance from a second end of the second wiring region, which is close to the third wiring region, to the portion connecting to the capacitive component is higher than the impedance in the first wiring region and the impedance in the third wiring region.

8. The wiring board according to claim 1,
wherein the reference voltage layer includes:
a first reference voltage layer disposed inside the substrate; and
a second reference voltage layer disposed to the first reference voltage layer with a first insulating layer disposed therebetween, the second reference voltage layer being more distant from the wiring pattern than the first reference voltage layer, and
wherein the first reference voltage layer is partially removed at a portion overlapping the wiring region when viewed from above.

9. The wiring board according to claim 8,
wherein the reference voltage layer includes a third reference voltage layer disposed on the second reference voltage layer with a second insulating layer being disposed therebetween, the third reference voltage layer being more distant from the wiring pattern than the first reference voltage layer and the second reference voltage layer, and
wherein the second reference voltage layer is partially removed at a portion overlapping the wiring region when viewed from above.

10. The wiring board according to claim 1, wherein the terminal is exposed for external connection.

11. The wiring board according to claim 1, wherein the capacitive component includes a transient voltage suppressor (TVS) diode or a Zener diode.

12. The wiring board according to claim 1,
wherein the signal includes differential signals,
wherein the terminal includes a first terminal and a second terminal configured to transmit the differential signals,
wherein the wiring pattern includes:
a first wiring pattern connecting to the first terminal; and
a second wiring pattern connecting to the second terminal,
wherein a line width of the first wiring pattern in a first wiring region including a portion connecting to a first capacitive component is narrower than a line width of the first wiring pattern other than the first wiring region,
wherein a line width of the second wiring pattern in a second wiring region including a portion connecting to a second capacitive component is narrower than a line width of the second wiring pattern other than the second wiring region.

13. The wiring board according to claim 12, wherein the differential signals include a signal for serial communication.

14. The wiring board according to claim 12, wherein the differential signals include a signal complying with a peripheral component interconnect (PCI) express standard or a universal flash storage (UFS) standard.

15. An electronic device comprising:
a wiring board having a first surface;
a controller circuitry mounted on the wiring board, and configured to transmit and receive a signal via a wiring pattern disposed to the wiring board; and
a capacitive component mounted on the first surface of the wiring board and connected to the wiring pattern,
the wiring board including:
a substrate having the first surface;
a terminal disposed to the first surface of the substrate;
the wiring pattern connected to the terminal on the first surface and configured to transmit the signal; and
a reference voltage layer to which a reference voltage is configured to be applied, the reference voltage layer being disposed inside the substrate or to a second surface, which is opposite to the first surface, wherein
a line width of the wiring pattern in a wiring region including a portion connecting to a capacitive component is narrower than a line width of the wiring pattern at a portion other than the wiring region,
the reference voltage layer is partially removed at a portion overlapping the wiring region when the substrate is viewed from above.

16. The electronic device according to claim 15, wherein the wiring pattern includes:
a first wiring region from the terminal to the wiring region;
a second wiring region including the wiring region; and
a third wiring region on an opposite side of the first wiring region relative to the wiring region,
a line width of the first wiring region being wider than a line width of the second wiring region and a line width of the third wiring region,
the line width of the third wiring region being wider than the line width of the second wiring region.

17. The electronic device according to claim 15,
wherein the reference voltage layer includes:
a first reference voltage layer disposed inside the substrate; and
a second reference voltage layer disposed to the first reference voltage layer with a first insulating layer disposed therebetween, the second reference voltage layer being more distant from the wiring pattern than the first reference voltage layer, and
wherein the first reference voltage layer is partially removed at a portion overlapping the wiring region when viewed from above.

18. The electronic device according to claim 15, wherein the terminal is exposed for external connection.

19. The electronic device according to claim 15, wherein the capacitive component includes a transient voltage suppressor (TVS) diode or a Zener diode.

20. The electronic device according to claim 15,
wherein the signal includes differential signals,
wherein the terminal includes a first terminal and a second terminal configured to transmit the differential signals,
wherein the wiring pattern includes:
a first wiring pattern connecting to the first terminal; and
a second wiring pattern connecting to the second terminal,
wherein a line width of the first wiring pattern in a first wiring region including a portion connecting to a first capacitive component is narrower than a line width of the first wiring pattern other than the first wiring region,
wherein a line width of the second wiring pattern in a second wiring region including a portion connecting to a second capacitive component is narrower than a line width of the second wiring pattern other than the second wiring region.
